(19) United States
(12) Patent Application Publication
(10) Pub. No.: US 2026/0362905 A1
(43) Pub. Date: Nov. 12, 2026

(54) DISPLAY DEVICE AND ELECTRONIC DEVICE INCLUDING THE SAME

(71) Applicant: Samsung Display Co., Ltd., Yongin-si (KR)

(72) Inventors: Dongsoup NOH, Yongin-si (KR); Juhyun SHIN, Yongin-si (KR); Yongsu JIN, Yongin-si (KR); Sungwoo KIM, Yongin-si (KR)

(73) Assignee: Samsung Display Co., Ltd., Yongin-si (KR)

(21) Appl. No.: 19/425,242

(22) Filed: Dec. 18, 2025

(30) Foreign Application Priority Data
May 12, 2025 (KR) 10-2025-0061460

(51) Int. Cl. H10K 59/122; H10K 59/121

(52) U.S. Cl. CPC H10K 59/122; H10K 59/1213

(57) ABSTRACT

A display device includes a display panel having a display area and a peripheral area, and the display panel includes a substrate, a thin-film transistor on the substrate, at least partially in the display area and including a semiconductor layer, a gate electrode, a source electrode, a drain electrode, a planarization insulating layer on the thin-film transistor and at least partially in the display area and the peripheral area, a pixel electrode on the planarization insulating layer at least partially in the display area and electrically connected to the thin-film transistor, an alignment mark on the planarization insulating layer at least partially in the peripheral area and including a first conductive layer, and a bank layer on the planarization insulating layer to cover a portion of the pixel electrode and defining a pixel opening exposing a portion of the pixel electrode.

### CROSS-REFERENCE TO RELATED APPLICATION

This application is based on and claims priority under 35 U.S.C. § 119 to Korean Patent Application No. 10-2025-0061460, filed on May 12, 2025, in the Korean Intellectual Property Office, the disclosure of which is incorporated by reference herein in its entirety.

### BACKGROUND

One or more example embodiments relate to a device, and more particularly, to a display device and/or to an electronic device.

Mobility-based electronic devices are widely used. In addition to small electronic devices such as mobile phones, tablet personal computers (PC) have been widely used in recent years as mobile electronic devices.

A mobile electronic device includes a display device that provides visual information, such as an image and/or a video, to a user. Such a device may support various functions. Recently, as the size of other components for driving a display device has been reduced, the proportion of the display device in an electronic device has gradually increased, and a structure that may be bent by a certain angle from a flat state has been developed.

### SUMMARY

One or more example embodiments include a display device including a display panel in which an alignment mark is easily recognized.

However, these objectives are examples, and the scope of example embodiments is not limited thereto.

Additional aspects will be set forth in part in the description which follows and, in part, will be apparent from the description, or may be learned by practice of example embodiments.

According to one or more example embodiments, a display device includes a display panel including a display area and a peripheral area, and the display panel includes a substrate, a thin-film transistor on the substrate, at least partly in the display area and including a semiconductor layer, a gate electrode, a source electrode, and a drain electrode, a planarization insulating layer on the thin-film transistor and at least partly in the display area and the peripheral area, a pixel electrode on the planarization insulating layer, at least partly in the display area and electrically connected to the thin-film transistor, an alignment mark on the planarization insulating layer, at least partly in the peripheral area and including a first conductive layer, and a bank layer on the planarization insulating layer, covering a portion of the pixel electrode, and defining a pixel opening exposing a portion of the pixel electrode, wherein the pixel electrode and the first conductive layer are in a same layer and include a same material, and the first conductive layer is spaced apart from the bank layer.

In some example embodiments, the first conductive layer may include a first portion, a second portion on the first portion and including a different material from the first portion, and a third portion on the second portion and including a same material as the first portion.

In some example embodiments, each of the first portion and the third portion may include an indium tin oxide (ITO) material, and the second portion may include a silver (Ag) material.

In some example embodiments, the display panel may further include a second conductive layer arranged between the substrate and the planarization insulating layer at least partly in the peripheral area, and the second conductive layer may be in a same layer as each of the source electrode and the drain electrode and may include a same material as each of the source electrode and the drain electrode.

In some example embodiments, the first conductive layer may be surrounded by the second conductive layer in a plan view.

In some example embodiments, each of the second conductive layer, the source electrode, and the drain electrode may independently include at least one material from among titanium (Ti) and aluminum (Al).

In some example embodiments, the display device may further include an optical functional layer on the display panel, and the optical functional layer may be aligned with the display panel by the alignment mark.

In some example embodiments, the optical functional layer may include a polarizing plate.

In some example embodiments, the display device may further include a planarization layer arranged between the optical functional layer and the display panel.

In some example embodiments, the display device may further include a cover window on the optical functional layer.

Alternatively or additionally according to some example embodiments, an electronic device includes a display panel including a display area and a peripheral area, and the display panel includes a substrate, a thin-film transistor on the substrate, at least partly in the display area and including a semiconductor layer, a gate electrode, a source electrode, and a drain electrode, a planarization insulating layer on the thin-film transistor, at least partly in the display area and the peripheral area, a pixel electrode on the planarization insulating layer at least partly in the display area and electrically connected to the thin-film transistor, an alignment mark on the planarization insulating layer at least partly in the peripheral area and including a first conductive layer, a second conductive layer arranged between the substrate and the planarization insulating layer at least partly in the peripheral area, and a bank layer on the planarization insulating layer covering a portion of the pixel electrode and defining a pixel opening exposing a portion of the pixel electrode, wherein the first conductive layer is spaced apart from the bank layer, and the first conductive layer is surrounded by the second conductive layer in a plan view.

In some example embodiments, the pixel electrode and the first conductive layer may be in a same layer and may include a same material.

In some example embodiments, the second conductive layer may be in a same layer as each of the source electrode and the drain electrode and may include a same material as each of the source electrode and the drain electrode.

In some example embodiments, the first conductive layer may include a first portion, a second portion on the first portion and including a different material from the first portion, and a third portion on the second portion and including a same material as the first portion.

In some example embodiments, each of the first portion and the third portion may include an ITO material, and the second portion may include an Ag material.

In some example embodiments, each of the second conductive layer, the source electrode, and the drain electrode may independently include at least one material from among Ti and Al.

In some example embodiments, the display device may further include an optical functional layer on the display panel, and the optical functional layer may be aligned with the display panel by the alignment mark.

In some example embodiments, the optical functional layer may include a polarizing plate.

In some example embodiments, the electronic device may further include a planarization layer arranged between the optical functional layer and the display panel.

In some example embodiments, the electronic device may further include a cover window disposed on the optical functional layer.

Other aspects, features, and advantages other than those described above will now become apparent from the following drawings, claims, and the detailed description of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1 and 2 are schematic plan views of a display device according to some example embodiments;

FIG. 3 is a circuit diagram schematically illustrating a light-emitting diode provided in a pixel of a display device according to some example embodiments and a pixel circuit connected to the light-emitting diode;

FIG. 4 is a schematic cross-sectional view of a display device according to some example embodiments;

FIG. 5 is a schematic plan view of a display device according to some example embodiments;

FIGS. 6 and 7 are schematic cross-sectional views of a display device according to some example embodiments;

FIG. 8 is a schematic plan view of a display device according to some example embodiments;

FIG. 9 is a schematic cross-sectional view of a display device according to some example embodiments;

FIG. 10 is a block diagram of an electronic device according to some example embodiments; and

FIG. 11 shows schematic diagrams of electronic devices according to various example embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b, and c” indicates only a, only b, only c, both a and b, both a and c, both b and c, all of a, b, and c, or variations thereof.

As the disclosure allows for various changes and numerous embodiments, particular embodiments will be illustrated in the drawings and described in detail in the written description. Effects and features of the disclosure and methods of achieving the same will be apparent with reference to embodiments and drawings described below in detail. The disclosure may, however, be embodied in many different forms and should not be construed as being limited to the embodiments set forth herein.

The disclosure will now be described more fully with reference to the accompanying drawings, in which embodiments are shown. Like reference numerals in the drawings denote like elements, and thus their description will not be repeated.

In the following embodiments, while such terms as “first,” “second,” etc., may be used to describe various elements, such elements must not be limited to the above terms.

In the following embodiments, an expression used in the singular encompasses the expression of the plural, unless it has a clearly different meaning in the context.

In the following embodiments, it is to be understood that the terms such as “including” and “having” are intended to indicate the existence of the features, or elements disclosed in the disclosure, and are not intended to preclude the possibility that one or more other features or elements may exist or may be added.

It will be understood that when a layer, region, or element is referred to as being formed on another layer, region, or element, it can be directly or indirectly formed on the other layer, region, or element, that is, for example, intervening layers, regions, or elements may be present.

Sizes of elements in the drawings may be exaggerated or reduced for convenience of explanation. For example, since sizes and thicknesses of components in the drawings are arbitrarily illustrated for convenience of explanation, the following embodiments are not limited thereto.

The x-axis, the y-axis, and the z-axis are not limited to three axes on the orthogonal coordinate system, and may be interpreted in a broad sense including the same. For example, the x-axis, the y-axis, and the z-axis may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

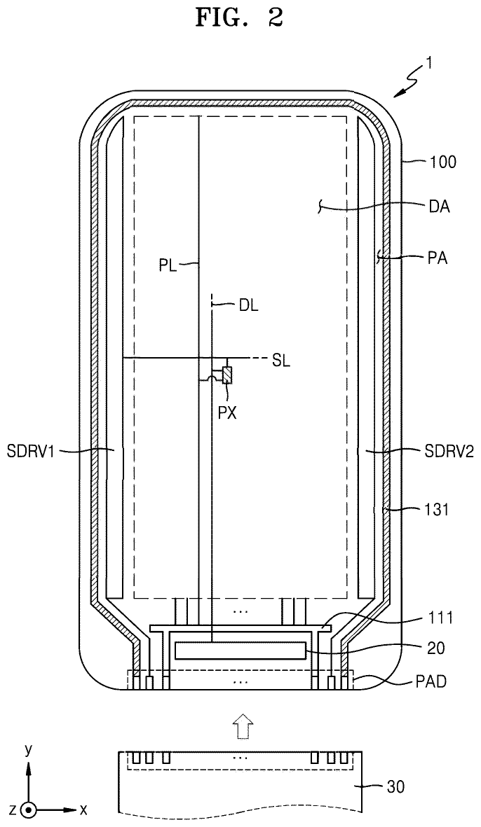

In the disclosure, “in a plan view” means a plan view viewed in a direction perpendicular to a substrate 100 (refer to FIG. 2). That is, “A and B are spaced apart from each other in a plan view” means “A and B are spaced apart from each other when viewed in a direction perpendicular to the substrate 100 (refer to FIG. 2).”

As used herein, “in a cross-sectional view” means a plan view cut in a direction perpendicular to the substrate 100 (refer to FIG. 2). That is, “A and B are spaced apart from each other in a cross-sectional view” means “A and B are spaced apart from each other in a plan view cut in a direction perpendicular to the substrate 100 (refer to FIG. 2).”

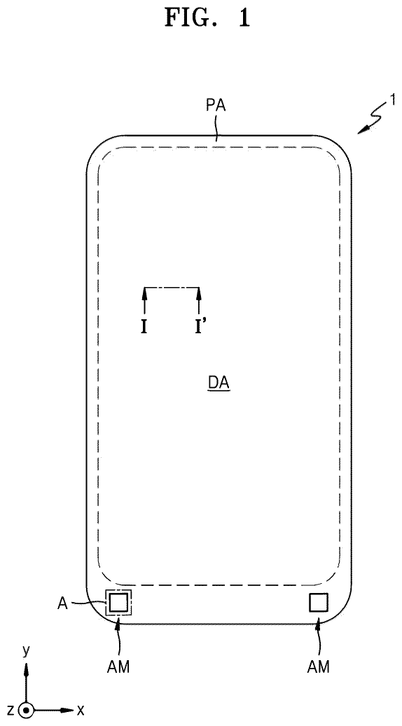

FIGS. 1 and 2 are schematic plan views of a display device 1 according to some example embodiments.

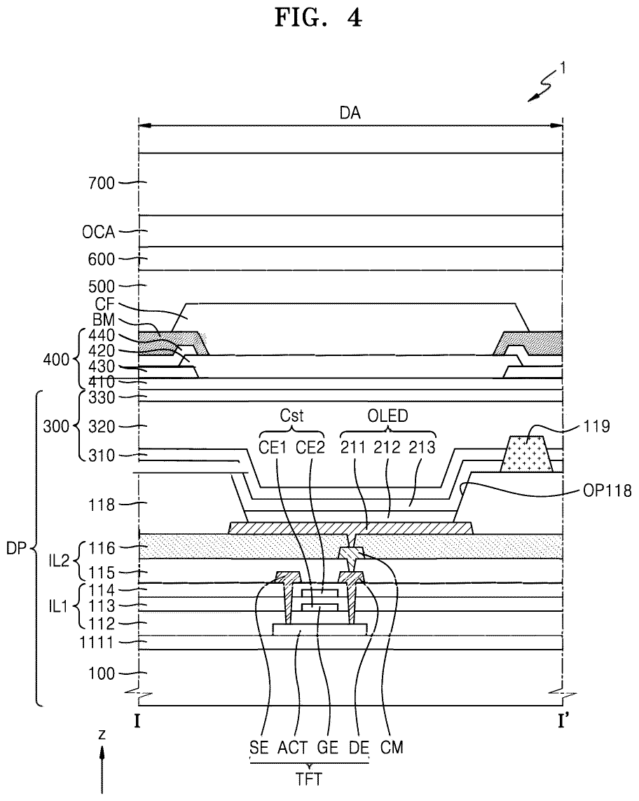

Referring to FIG. 1, the display device 1 includes or has a display area DA and a peripheral area PA outside (or on the periphery of) the display area DA. In some example embodiments, a front face of the display device 1 may be partitioned into the display area DA and the peripheral area PA. Because the display device 1 includes a display panel DP (refer to FIG. 4), the display panel DP may be considered to include the display area DA and the peripheral area PA. Alternatively, it may be understood that the display area DA and the peripheral area PA are defined in the display panel DP. In some example embodiments, because the display device 1 includes the substrate 100 (refer to FIG. 2), the substrate 100 (refer to FIG. 2) may be considered to include the display area DA and the peripheral area PA. Alternatively, it may be understood that the display area DA and the peripheral area PA are defined in the substrate 100 (refer to FIG. 2).

The display area DA is or includes a portion that displays an image, and a plurality of pixels may be disposed therein. The display area DA may have various shapes, for example, a circular shape, an oval shape, a polygonal shape, a shape of a particular figure, or the like. In FIG. 1, the display area DA is shown to have a substantially rectangular shape with rounded corners. The peripheral area PA may be disposed outside the display area DA. The peripheral area PA may be disposed to surround at least a portion of the display area DA.

Hereinafter, an organic light-emitting display device is described as an example of the display device 1 according to some example embodiments. However, the display device in the disclosure is not limited thereto. Alternatively or additionally, the display device 1 in the disclosure may be or may include a display device such as one or more of an inorganic light-emitting display device, an inorganic electroluminescence (EL) display device, or a quantum dot light-emitting display device. For example, an emission layer of a display element provided in the display device 1 may include one or more of an organic material, an inorganic material, a quantum dot, an organic material and a quantum dot, or an inorganic material and a quantum dot.

Referring to FIG. 2, the display device 1 includes the substrate 100. Various components forming the display device 1 are disposed on the substrate 100. The substrate 100 includes the display area DA and the peripheral area PA outside the display area DA. As described herein, any component being positioned in the display area DA means or indicates that the component is disposed in the display area DA of the substrate 100 and/or is disposed to overlap or be within the display area DA of the substrate 100. Similarly, as described herein, any component being positioned in the peripheral area PA means or indicates that the component is disposed in the peripheral area PA of the substrate 100 or is disposed to overlap or be within the peripheral area PA of the substrate 100.

A plurality of pixels PX may be disposed in the display area DA. Each of the pixels PX may be implemented as a light-emitting diode such as an organic light-emitting diode. Each of the pixels PX may emit, for example, red, green, blue, or white light, e.g. may emit a narrow-band or a broad-band spectrum of light.

Pixel circuits driving the pixels PX may be connected to signal lines or voltage lines; the signal lines or voltage lines may be configured to control the on/off and/or the brightness or the like of light-emitting diodes. For example, FIG. 2 shows a scan line SL extending in a first direction (e.g., an x-axis direction) and a data line DL extending in a second direction (e.g., a y-axis direction) as signal lines and a driving voltage line PL as a voltage line.

The peripheral area PA may be or may include a non-display area that does not display an image. In some example embodiments, the peripheral area PA may entirely surround the display area DA. The peripheral area PA includes outer circuits configured to drive the pixels PX. For example, a first scan driver SDRV1, a second scan driver SDRV2, a data driver 20, a terminal portion PAD, a driving voltage supply line 111, and a common voltage supply line 131 may be disposed in the peripheral area PA.

The first scan driver SDRV1 may apply a scan signal to each of the pixel circuits driving the pixels PX via the scan line SL. In some example embodiments, the second scan driver SDRV2 may be positioned on the opposite side of the first scan driver SDRV1 with the display area DA therebetween and may be substantially parallel with the first scan driver SDRV1; however, example embodiments are not limited thereto. Some of the pixel circuits of the pixels PX disposed in the display area DA may be electrically connected to the first scan driver SDRV1, and the remaining pixel circuits may be electrically connected to the second scan driver SDRV2.

The data driver 20 may include an integrated circuit (e.g., a driving chip) that drives the display device 1. Such an integrated circuit may be or may include (or be included in) a data driving integrated circuit that generates data signals, but example embodiments are not limited thereto. The data driver 20 may include a plurality of terminals. The data driver 20 may be electrically connected to a printed circuit board 30 attached on one side of the display device 1 via the terminals. Alternatively or additionally, the data driver 20 may also be or have at least one component provided on the printed circuit board 30.

The terminal portion PAD may be disposed on one side of the substrate 100. The terminal portion PAD may be exposed by not being covered by an insulating layer and may be connected to the printed circuit board 30.

A controller (not shown) may be disposed in the printed circuit board 30. The controller may generate control signals to be transmitted to the first scan driver SDRV1 and the second scan driver SDRV2. In some example embodiments, the controller may supply a driving voltage ELVDD to the driving voltage supply line 111 and may supply a common voltage ELVSS to the common voltage supply line 131. The driving voltage ELVDD may be applied to the pixel circuits of the pixels PX via the driving voltage line PL connected to the driving voltage supply line 111, and the common voltage ELVSS may be applied to an opposite electrode of a light-emitting diode connected to the common voltage supply line 131. The driving voltage supply line 111 may be provided below the display area DA to extend in the first direction (e.g., the x-axis direction). The common voltage supply line 131 may have a loop shape with one side open to partially surround the display area DA; example embodiments are not limited thereto.

The controller may generate a data signal, and the generated data signal may be transmitted to the data line DL through the data driver 20. The data signal may be sequentially transmitted to the pixels PX positioned in the same column through the data lines DL extending in the second direction (e.g., the y-axis direction). In some example embodiments, the controller may generate a touch driving signal to be transmitted to each of sensor electrodes of a touch sensor layer.

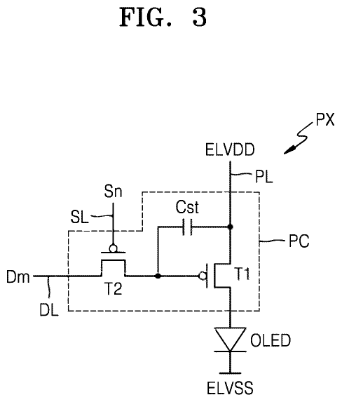

FIG. 3 is a circuit diagram schematically illustrating a light-emitting diode provided in a pixel PX of a display device according to some example embodiments and a pixel circuit PC connected to the light-emitting diode.

Referring to FIG. 3, the pixel circuit PC may be connected to a light-emitting diode, such as an organic light-emitting diode OLED, to implement light emission of the pixels PX. The pixel circuit PC includes a driving transistor T1, a switching transistor T2, and a storage capacitor Cst. The switching transistor T2 is connected to the scan line SL and the data line DL, and is configured to deliver to the driving thin-film transistor T1, a data signal Dm input through the data line DL, in accordance to a scan signal Sn input through the scan line SL.

The storage capacitor Cst is connected to the switching transistor T2 and a driving voltage line PL, and stores a voltage corresponding to a difference between a voltage received from the switching thin-film transistor T2 and a driving voltage ELVDD supplied to the driving voltage line PL.

The driving transistor T1 may be connected to the driving voltage line PL and the storage capacitor Cst, and may control a driving current flowing from the driving voltage line PL to the organic light-emitting diode OLED, in accordance with a voltage value stored in the storage capacitor Cst. The organic light-emitting diode OLED may emit light having a certain brightness according to the driving current.

The pixel circuit PC is not limited to the number of thin-film transistors, the number of storage capacitors, and the circuit design described with reference to FIG. 3, and the number of thin-film transistors, the number of storage capacitors, and/or the circuit design may be variously changed.

For example, either or both of the driving transistor T1 and the switching transistor T2 may be or may a thin-film transistor and/or a metal-oxide-semiconductor transistor. Either or both driving transistor T1 and the switching transistor T2 may be P-type transistor or an N-type transistor; example embodiments are not limited thereto. Alternatively or additionally, the storage capacitor Cst may be a planar capacitor such as a metal-insulator-metal (MIM) capacitor; example embodiments are not limited thereto.

FIG. 4 is a schematic cross-sectional view of the display device 1 according to some example embodiments.

In particular, FIG. 4 is a cross-sectional view of the display device 1, taken along a line I-I′ of FIG. 1.

Referring to FIG. 4, the display device 1 may include the display panel DP, a touch layer 400, a light-blocking member BM, a color filter CF, a planarization layer 500, an optical functional layer 600, an adhesive OCA, and a cover window 700.

The display panel DP may include the substrate 100, a buffer layer 1111, an inorganic insulating layer IL1, a planarization insulating layer IL2, a bank layer 118, a thin-film transistor TFT, a connection electrode CM, an organic light-emitting diode OLED, and an encapsulation layer 300.

The substrate 100 may include a glass material and/or a polymer resin. In some example embodiments, the substrate 100 may include a plurality of sub-layers. The plurality of sub-layers may have a structure in which organic layers and inorganic layers are alternately stacked. When the substrate 100 includes a polymer resin, the substrate 100 may include one or more of polyethersulfone, polyacrylate, polyetherimide, polyethylene naphthalate, polyethylene terephthalate, polyphenylene sulfide, polyarylate, polyimide, polycarbonate, or cellulose acetate propionate.

The buffer layer 1111 may be formed on the substrate 100 to prevent or reduce the likelihood of and/or the impact from impurities penetrating into a semiconductor layer ACT of the thin-film transistor TFT. The buffer layer 1111 may include an inorganic insulating material such as one or more of silicon nitride, silicon oxynitride, and silicon oxide, and may be a single layer or a multilayer, each including the above-described inorganic insulating material.

The thin-film transistor TFT may be disposed on the substrate 100 to be overlapped by the display area DA. The thin-film transistor TFT may include the semiconductor layer ACT, a gate electrode GE, a source electrode SE, and a drain electrode DE.

The semiconductor layer ACT may be disposed on the buffer layer 1111. The semiconductor layer ACT may be divided into a source area, a drain area, and a channel area between the source area and the drain area, the source area and the drain area being doped with impurities such as but not limited to one or more of boron, phosphorus, or arsenic. The semiconductor layer ACT may include an oxide semiconductor. Alternatively or additionally, the semiconductor layer ACT may include one or more of amorphous silicon, polysilicon, or an organic semiconductor.

The inorganic insulating layer IL1 may be disposed on the buffer layer 1111. The inorganic insulating layer IL1 may include a first inorganic insulating layer 112, a second inorganic insulating layer 113 disposed on the first inorganic insulating layer 112, and a third inorganic insulating layer 114 disposed on the second inorganic insulating layer 113. Each of the first inorganic insulating layer 112, the second inorganic insulating layer 113, and the third inorganic insulating layer 114 may include, e.g., may independently or concurrently include, an inorganic insulating material, such as one or more of silicon oxide, silicon nitride, silicon oxynitride, aluminum oxide, titanium oxide, tantalum oxide, hafnium oxide, or the like. Each of the first inorganic insulating layer 112, the second inorganic insulating layer 113, and the third inorganic insulating layer 114 may include, e.g., may independently or concurrently include a single layer or a multi-layer, each including the above-described material.

The first inorganic insulating layer 112 may be disposed on the buffer layer 1111. The first inorganic insulating layer 112 may cover (e.g., may conformally cover) the semiconductor layer ACT in the display area DA and may be continuously disposed on the substrate 100. However, example embodiments are not limited thereto.

The gate electrode GE may be disposed on the first inorganic insulating layer 112. The gate electrode GE may overlap, e.g., may fully or at least partially overlap, the channel area of the semiconductor layer ACT. The gate electrode GE may include a low-resistance metal material. The gate electrode GE may include a conductive material including one or more of molybdenum (Mo), aluminum (Al), copper (Cu), titanium (Ti), or the like, and may include a multi-layer or a single layer, each including one or more of the material stated above.

The second inorganic insulating layer 113 may be disposed on the first inorganic insulating layer 112. In some example embodiments, the second inorganic insulating layer 113 may be continuously disposed above the substrate 100 to cover the gate electrode GE. However, example embodiments are not limited thereto.

An upper electrode CE2 may be disposed on the second inorganic insulating layer 113 to overlap the display area DA. The upper electrode CE2 may be or may include a capacitor electrode. The upper electrode CE2 may include a conductive material including one or more of Mo, Al, Cu, Ti, or the like, and may include a multi-layer or a single layer, each including one or more of the above material. A lower electrode CE1, which is integral with, e.g., is the same as, the gate electrode GE, may be disposed below the upper electrode CE2. The upper electrode CE2 and the lower electrode CE1 may configure a storage capacitor Cst, e.g., may configure the storage capacitor Cst described above with reference to FIG. 3.

The third inorganic insulating layer 114 may be disposed on the second inorganic insulating layer 113. In some example embodiments, the third inorganic insulating layer 114 may cover the upper electrode CE2 and may be continuously disposed above the substrate 100. However, example embodiments are not limited thereto.

The source electrode SE and the drain electrode DE may be disposed on the third inorganic insulating layer 114. The source electrode SE may be connected to the source area of the semiconductor layer ACT through a contact hole formed in the inorganic insulating layer IL1. The drain electrode DE may be connected to the drain area of the semiconductor layer ACT through a contact hole formed in the inorganic insulating layer IL1.

The source electrode SE and the drain electrode DE may each include a material having good conductivity, and may or may not include the same material. Each of the source electrode SE and the drain electrode DE may include a conductive material including one or more of Mo, Al, Cu, Ti, or the like, and may include a multi-layer or a single layer, each including one or more of the above material. For example, each of the source electrode SE and the drain electrode DE may include a multi-layer of Ti/Al/Ti.

The planarization insulating layer IL2 may be disposed on the inorganic insulating layer IL1 and the thin-film transistor TFT. The planarization insulating layer IL2 may include a first planarization insulating layer 115 and a second planarization insulating layer 116 disposed on the first planarization insulating layer 115. The first planarization insulating layer 115 and the second planarization insulating layer 116 may each include a general commercial polymer such as poly(methyl methacrylate) (PMMA) or polystyrene (PS), a polymer derivative having a phenol group, and an organic insulating material, such as an acrylic polymer, an imide polymer, an aryl ether polymer, an amide polymer, a fluorine polymer, a p-xylene polymer, a vinyl alcohol polymer, and a mixture thereof. In some example embodiments, the first planarization insulating layer 115 and the second planarization insulating layer 116 may each include polyimide.

The first planarization insulating layer 115 may be disposed on the third inorganic insulating layer 114. In some example embodiments, the first planarization insulating layer 115 may be continuously disposed above the substrate 100 to cover the source electrode SE and the drain electrode DE. However, example embodiments are not limited thereto.

The connection electrode CM may be disposed on the first planarization insulating layer 115. The connection electrode CM may be connected to the drain electrode DE and/or the source electrode SE through a contact hole formed in the first planarization insulating layer 115. The connection electrode CM may include a conductive material including one or more of Mo, Al, Cu, Ti, or the like, and may include a multi-layer or a single layer, each including one or more of the above material. In some example embodiments, the connection electrode CM may include a multi-layer of Ti/Al/Ti.

The second planarization insulating layer 116 may be disposed on the first planarization insulating layer 115. The second planarization insulating layer 116 may be continuously disposed above the substrate 100 to cover the connection electrode CM. However, example embodiments are not limited thereto.

The organic light-emitting diode OLED may be disposed on the second planarization insulating layer 116 to be overlapped by the display area DA. The organic light-emitting diode OLED may include a pixel electrode 211, an intermediate layer 212, and an opposite electrode 213.

The pixel electrode 211 may be disposed on the planarization insulating layer IL2 (particularly the second planarization insulating layer 116) to be overlapped by or to be in the display area DA. The pixel electrode 211 may be connected to the connection electrode CM through a contact hole formed in the second planarization insulating layer 116. Accordingly, the pixel electrode 211 may be electrically connected to the thin-film transistor TFT.

The pixel electrode 211 may include a conductive oxide such as one or more of indium tin oxide (ITO), indium zinc oxide (IZO), zinc oxide (ZnO), indium oxide (In2O3), indium gallium oxide (IGO), or aluminum zinc oxide (AZO). Alternatively or additionally, the pixel electrode 211 may include a reflective film including silver (Ag), Mg, Al, platinum (Pt), palladium (Pd), gold (Au), nickel (Ni), neodymium (Nd), iridium (Ir), chromium (Cr), or a compound thereof. Alternatively or additionally, the pixel electrode 211 may further include a film including ITO, IZO, ZnO, or In2O3 above and/or below the reflective film described above.

The bank layer 118 may be disposed on the planarization insulating layer IL2 (particularly the second planarization insulating layer 116) to cover a portion of the pixel electrode 211. The bank layer 118 may include or define or have a sidewall surface thereof defining a pixel opening OP118 exposing a portion of the pixel electrode 211. For example, the bank layer 118 may include an organic material.

The bank layer 118 may include an inorganic insulating material such as one or more of silicon nitride, silicon oxynitride, or silicon oxide. Alternatively, the bank layer 118 may include an organic insulating material and an inorganic insulating material.

A spacer 119 may be disposed on the bank layer 118. For example, the spacer 119 may include an organic material. The spacer 119 may maintain a gap between the encapsulation layer 300 and the substrate 100. For example, the spacer 119 may include the same material as the bank layer 118.

The intermediate layer 212 may be disposed on the pixel electrode 211. The intermediate layer 212 may be disposed in the pixel opening OP118 formed in the bank layer 118. In some example embodiments, the intermediate layer 212 may have a multi-layered structure including a hole injection layer, a hole transport layer, an organic emission layer, an electron transport layer, and an electron injection layer. The organic emission layer may include a light-emitting material.

The opposite electrode 213 may cover the intermediate layer 212 and may be disposed on the bank layer 118. In some example embodiments, the opposite electrode 213 may be transparent or reflective. The opposite electrode 213 may be continuously disposed above the substrate 100. The opposite electrode 213 may include a conductive material having a low work function. For example, the opposite electrode 213 may include a (semi)transparent layer, the (semi)transparent layer including Ag, Mg, Al, Pt, Pd, Au, Ni, Nd, Ir, Cr, Li, Ca, alloys thereof, or the like. Alternatively or additionally, the opposite electrode 213 may further include a layer, such as ITO, IZO, ZnO, or In2O3, above the (semi)transparent layer including the material stated above.

The encapsulation layer 300 may prevent or reduce the likelihood of and/or the impact from external moisture and oxygen from penetrating into the organic light-emitting diode OLED. For example, the encapsulation layer 300 may include a first inorganic encapsulation layer 310, an organic encapsulation layer 320, and a second inorganic encapsulation layer 330.

The first inorganic encapsulation layer 310 may cover the opposite electrode 213 and may include silicon oxide, silicon nitride, and/or silicon oxynitride. Although not shown in the drawing, other layers, such as a capping layer or the like, may also be arranged between the first inorganic encapsulation layer 310 and the opposite electrode 213 as necessary. Because the first inorganic encapsulation layer 310 is formed along an underlying structure, an upper surface of the first inorganic encapsulation layer 310 may not be flat.

The organic encapsulation layer 320 may cover the first inorganic encapsulation layer 310, and unlike the first inorganic encapsulation layer 310, an upper surface of the organic encapsulation layer 320 may be formed substantially flat. In particular, the organic encapsulation layer 320 may have a substantially flat upper surface in a portion corresponding to the display area DA. The organic encapsulation layer 320 may include one or more materials selected from a group consisting of, or the group including, polyethylene terephthalate, polyethylene naphthalate, polycarbonate, polyimide, polyethylene sulfonate, polyoxymethylene, polyarylate, hexamethyldisiloxane, and an acrylic-based resin (e.g., polymethyl methacrylate, polyacrylic acid, or the like).

The second inorganic encapsulation layer 330 may cover the organic encapsulation layer 320 and may include silicon oxide, silicon nitride, and/or silicon oxynitride.

According to the above-described multi-layered structure of the encapsulation layer 300, even when cracks occur in the encapsulation layer 300, the encapsulation layer 300 may prevent or reduce the likelihood that and/or the impact from the cracks connecting between the first inorganic encapsulation layer 310 and the organic encapsulation layer 320 or between the organic encapsulation layer 320 and the second inorganic encapsulation layer 330. Accordingly, the formation of a path through which external moisture or oxygen, or the like penetrates into the display area DA, may be prevented or reduced in likelihood of occurrence and/or in impact.

The touch layer 400 may be disposed on the display panel DP. The touch layer 400 may include a first touch insulating layer 410, a second touch insulating layer 420, a first touch electrode 430, and a second touch electrode 440.

The first touch insulating layer 410 may be disposed on the encapsulation layer 300. The first touch insulating layer 410 may include silicon oxide, silicon nitride, silicon oxynitride, or the like. The above materials may be used alone or in combination with each other.

The first touch electrode 430 may be disposed on the first touch insulating layer 410. In some example embodiments, the first touch electrode 430 may be arranged in a non-emission area. For example, the first touch electrode 430 may overlap, e.g., may fully overlap or at least partially overlap, the bank layer 118. The first touch electrode 430 may include a metal, an alloy, a conductive metal oxide, a transparent conductive material, or the like.

The second touch insulating layer 420 may cover the first touch electrode 430. The second touch insulating layer 420 may include an inorganic insulating material. The second touch insulating layer 420 may include one or more of silicon oxide, silicon nitride, silicon oxynitride, or the like. The above materials may be used alone or in combination with each other. A contact hole may be defined in the second touch insulating layer 420 to expose a portion of the first touch electrode 430.

The second touch electrode 440 may be disposed on the second touch insulating layer 420 and may overlap the first touch electrode 430. For example, the second touch electrode 440 may be arranged in the non-emission area of the display device 1. The second touch electrode 440 may be electrically connected to the first touch electrode 430 through the contact hole exposing a portion of the first touch electrode 430. The second touch electrode 440 may include one or more of a metal, an alloy, a conductive metal oxide, a transparent conductive material, or the like.

The first touch electrode 430 and the second touch electrode 440 may configure a touch electrode. In some example embodiments, the touch electrode may have a mesh structure in a plane view. However, example embodiments are not limited thereto, and the structure of the touch electrode may vary.

The light-blocking member BM may be disposed on the second touch insulating layer 420. In some example embodiments, the light-blocking member BM may entirely overlap the non-emission area and may have a grid shape in a plan view. For example, the light-blocking member BM may overlap or at least partially overlap the bank layer 118 and the touch electrode. In some example embodiments, the light-blocking member BM may cover the second touch electrode 440.

The light-blocking member BM may absorb external light. Accordingly, the light-blocking member BM may reduce reflectance of external light of the display device 1. The light-blocking member BM may include at least one of carbon black, a back pigment, and a black dye. The above materials may be used alone or in combination with each other.

In some example embodiments, the light-blocking member BM may define a plurality of openings exposing a portion of the second touch insulating layer 420. For example, the light-blocking member BM may define an opening corresponding to the organic light-emitting diode OLED. For example, the opening may fully or at least partially overlap the organic light-emitting diode OLED.

Alternatively or additionally in some example embodiments, a touch protective layer (not shown) may be further arranged between the second touch insulating layer 420 and the light-blocking member BM. In this case, the second touch electrode 440 may be covered by the touch protective layer. The light-blocking member BM may full or at least partially overlap the touch electrode on the touch protective layer. Examples of the materials that may be used as the touch protective layer may include one or more of silicon oxide, silicon nitride, silicon oxynitride, or the like. The above materials may be used alone or in combination with each other.

The color filter CF may be disposed on the second touch insulating layer 420. When the touch protective layer is further arranged, the color filter CF may also be disposed on the touch protective layer.

The color filter CF may be arranged in the opening defined by the light-blocking member BM. In some example embodiments, the color filter CF may partially overlap the light-blocking member BM. The color of light emitted by the organic light-emitting diode OLED may be seen more clearly as the light passes through the color filter CF.

In some example embodiments, the color filter CF may allow light of a particular color to pass through and may block light of colors other than the particular color. For example, the color filter CF may include a dye and/or pigment that absorbs light of colors other than the particular color.

The planarization layer 500 may be disposed on the light-blocking member BM and the color filter CF. The planarization layer 500 may cover the light-blocking member BM and the color filter CF. Accordingly, the reliability of the light-blocking member BM and the color filter CF may be improved. In some example embodiments, the planarization layer 500 may have a substantially flat upper surface. Accordingly, the planarization layer 500 may compensate for a step-difference on the lower surface thereof. In some example embodiments, the planarization layer 500 may include an organic material. Examples of the materials that may be used as the planarization layer 500 may include one or more of photoresist, polyacrylic resin, polyimide resin, acrylic resin, epoxy resin, acrylate resin, or the like. The above materials may be used alone or in combination with each other.

For example, the light-blocking member BM and the color filter CF may be omitted. For example, the above-described example embodiments may also be applied to the case in which the display device 1 has a general organic light-emitting display structure instead of a quantum dot (QD) display structure. In such a structure, the planarization layer 500 may be disposed on the touch layer 400 to cover the touch layer 400 without the light-blocking member BM and the color filter CF, and thus the planarization layer 500 may planarize an upper portion of the touch layer 400.

The optical functional layer 600 may be disposed on the planarization layer 500. For example, the planarization layer 500 may be arranged between the optical functional layer 600 and the display panel DP. The optical functional layer 600 may be or may include (or be included in) a polarizing plate. However, example embodiments are not limited thereto. The adhesive OCA may be disposed on the optical functional layer 600, and the cover window 700 may be disposed on the adhesive OCA.

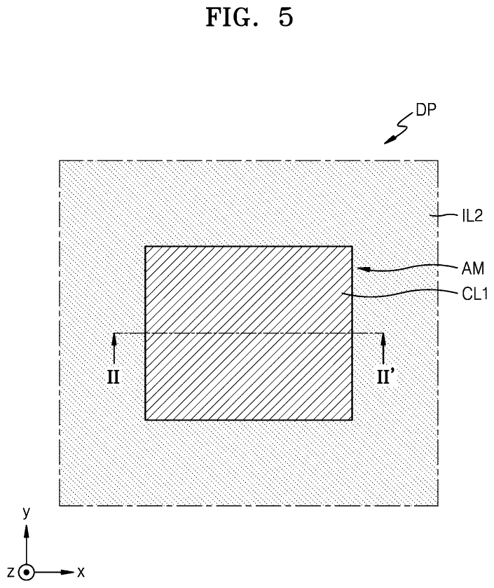

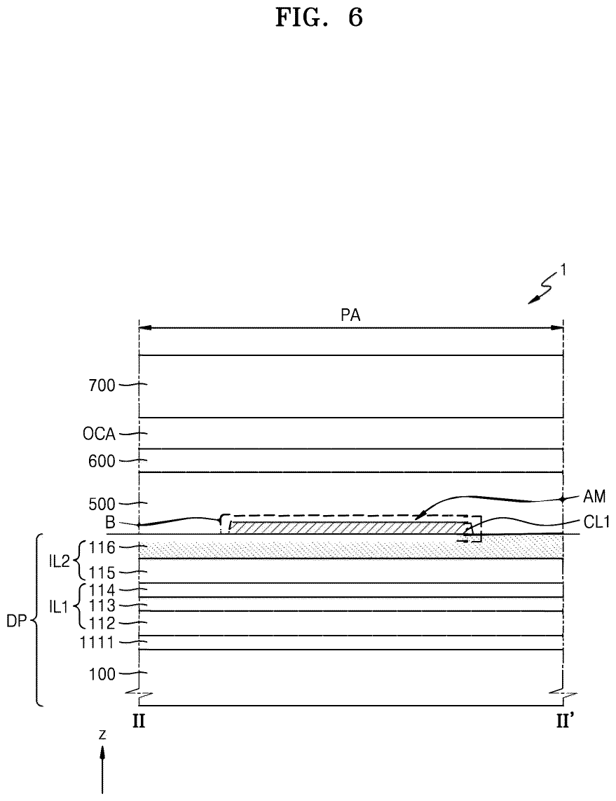

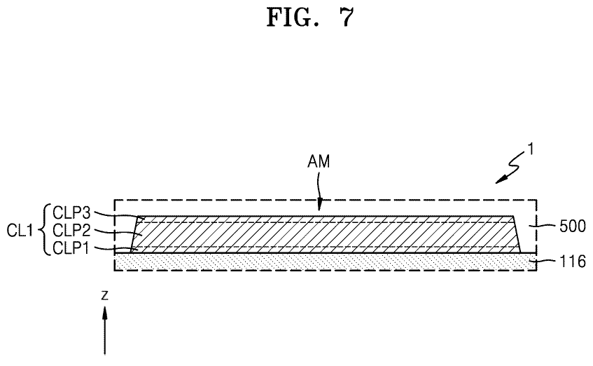

FIG. 5 is a schematic plan view of the display device 1 according to some example embodiments, and FIGS. 6 and 7 are schematic cross-sectional views of the display device 1 according to some example embodiments.

In particular, FIG. 5 is an enlarged view of the display device 1 according to a region A in FIG. 1, FIG. 6 is a cross-sectional view of the display device 1, taken along a line II-II′ of FIG. 5, and FIG. 7 is an enlarged view of the display device 1 according to a region B of FIG. 6.

Referring to FIGS. 5 to 7, in the peripheral area PA, the display panel DP may include the substrate 100, the buffer layer 1111, the inorganic insulating layer IL1, the planarization insulating layer IL2, and an alignment mark AM. In particular, the inorganic insulating layer IL1 may include the first inorganic insulating layer 112, the second inorganic insulating layer 113, and the third inorganic insulating layer 114. In addition, the planarization insulating layer IL2 may include the first planarization insulating layer 115 and the second planarization insulating layer 116. The substrate 100, the buffer layer 1111, the inorganic insulating layer IL1, and the planarization insulating layer IL2 may be arranged to be overlapped by the display area DA (refer to FIG. 4) and the peripheral area PA.

The alignment mark AM may be disposed on the planarization insulating layer IL2 (particularly the second planarization insulating layer 116) to be overlapped by the peripheral area PA. The alignment mark AM may include a first conductive layer CL1. The first conductive layer CL1 may be spaced apart from the bank layer 118 (refer to FIG. 4). As shown in FIG. 5, in a plan view, the first conductive layer CL1 may be surrounded by the planarization insulating layer IL2. Due to the difference in reflectance between the first conductive layer CL1 and the planarization insulating layer IL2, the alignment mark AM may be clearly recognized on the upper portion of the display panel DP.

The pixel electrode 211 (refer to FIG. 4) and the first conductive layer CL1 may be disposed in the same layer and may include the same material. The first conductive layer CL1 may include a first portion CLP1, a second portion CLP2 disposed on the first portion CLP1, and a third portion CLP3 on the second portion CLP2. The first portion CLP1 and the third portion CLP3 may include the same material, e.g., may be formed of the same materials. The second portion CLP2 may include a different material from the first portion CLP1 and the third portion CLP3. For example, each of the first portion CLP1 and the third portion CLP3 may include an indium tin oxide (ITO) material and in some cases may not include silver, and the second portion CLP2 may include a silver (Ag) material and in some cases may not include ITO. In such a structure, the pixel electrode 211 (refer to FIG. 4) may also be provided in a stacked structure of ITO/Ag/ITO.

The planarization layer 500 may be disposed on the planarization insulating layer IL2 to cover the first conductive layer CL1. In some example embodiments, the planarization layer 500 may have a substantially flat upper surface. Accordingly, the planarization layer 500 may compensate for, or at least help compensate for, a step-difference on the lower surface thereof. The optical functional layer 600 may be disposed on the planarization layer 500. In a process of attaching the display panel DP to the optical functional layer 600, the alignment mark AM may perform a mark function of aligning the display panel DP and the optical functional layer 600. For example, the optical functional layer 600 may be aligned with the display panel DP by the alignment mark AM. An adhesive may be disposed on the optical functional layer 600, and a cover window may be disposed on the adhesive.

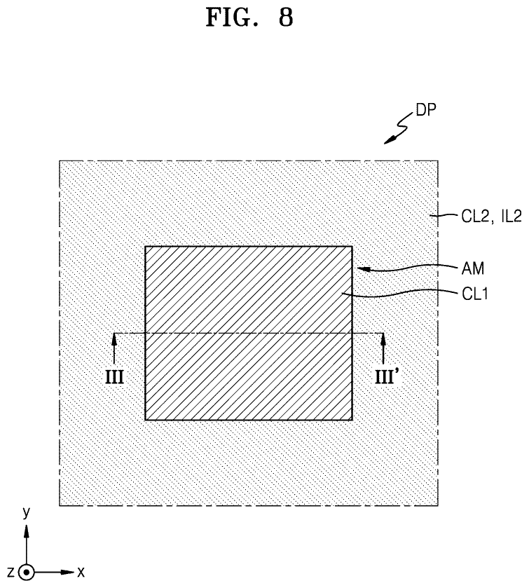

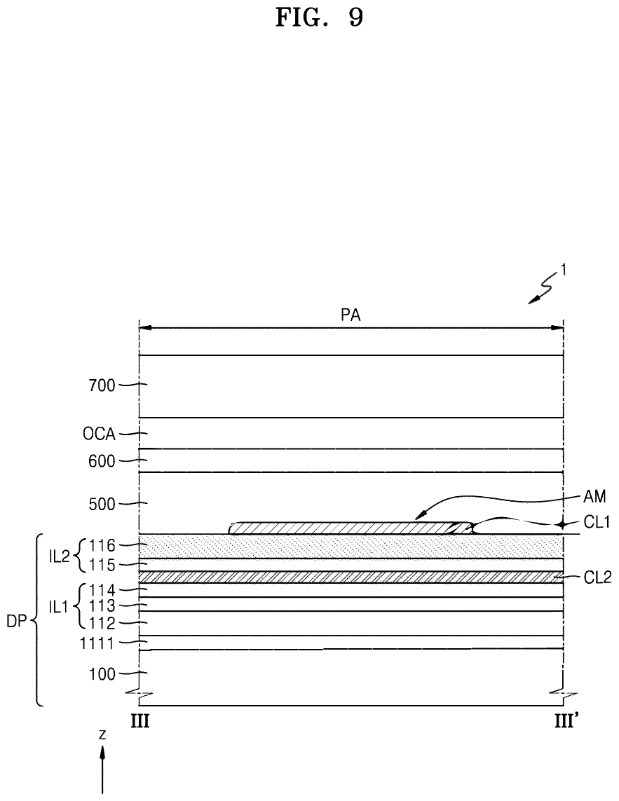

FIG. 8 is a schematic plan view of the display device 1 according to some example embodiments, and FIG. 9 is a schematic cross-sectional view of the display device 1 according to some example embodiments.

In particular, FIG. 8 is an enlarged view of the display device 1 according to the region A of FIG. 1, and FIG. 9 is a cross-sectional view of the display device 1, taken along a line III-III of FIG. 8.

In FIGS. 8 and 9, the same reference numerals as those in FIGS. 5 to 7 refer to the same members, and redundant descriptions thereof are omitted.

Referring to FIGS. 8 and 9, the display panel DP may include a second conductive layer CL2. The second conductive layer CL2 may be arranged between the substrate 100 and the planarization insulating layer IL2 to overlap the peripheral area PA. In particular, the second conductive layer CL2 may be arranged between the inorganic insulating layer IL1 and the planarization insulating layer IL2. In some example embodiments, the second conductive layer CL2 may be arranged between the third inorganic insulating layer 114 and the first planarization insulating layer 115.

The second conductive layer CL2 may be disposed in the same layer as each of the source electrode SE (refer to FIG. 4) and the drain electrode DE (refer to FIG. 4) and may include the same material as the source electrode SE (refer to FIG. 4) and the drain electrode DE (refer to FIG. 4). The second conductive layer CL2, the source electrode SE (refer to FIG. 4), and the drain electrode DE (refer to FIG. 4) may each include at least one material from among Ti and Al; in some cases, the second conductive layer CL2, the source electrode SE, and the drain electrode DE may independently include at least one material selected from among Ti and Al. That is, in some cases in some cases, the second conductive layer CL2, the source electrode SE, and the drain electrode DE may include the same and/or different materials selected from among Ti and Al. For example, the second conductive layer CL2, the source electrode SE (refer to FIG. 4), and the drain electrode DE (refer to FIG. 4) may each have a stacked structure of Ti/Al/Ti.

In a plan view, the first conductive layer CL1 may be surrounded by the second conductive layer CL2. Because the first conductive layer CL1 includes the same material as the pixel electrode 211 (refer to FIG. 4), the alignment mark AM may be more clearly recognized on the upper portion of the display panel DP due to the difference in reflectance between the first conductive layer CL1 and the second conductive layer CL2. This may improve the process of fabricating the display device.

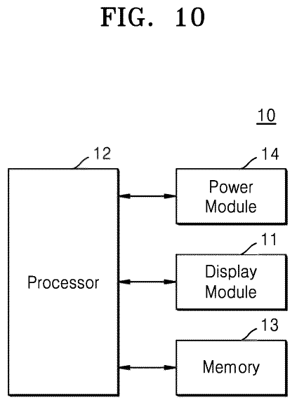

FIG. 10 is a block diagram of an electronic device according to some example embodiments.

Referring to FIG. 10, an electronic device 10 according to some example embodiments may include a display module 11, a processor 12, a memory 13, and a power module 14.

The processor 12 may include at least one of a central processing unit (CPU), an application processor (AP), a graphics processing unit (GPU), a communication processor (CP), an image signal processor (ISP), and a controller.

Data information necessary for, or used for, an operation of the processor 12 and/or the display module 11 may be stored in the memory 13. When the processor 12 executes an application stored in the memory 13, an image data signal and/or input control signal may be transmitted to the display module 11, and the display module 11 may process the received signal and may output image information through a display screen.

The power module 14 may include a power supply module, such as a power adapter and/or a battery device, and a power conversion module that generates power necessary for an operation of the electronic device 10 by converting power supplied by the power supply module.

At least one of the configurations of the electronic device 10 described above may be included in the display device according to one or more of the example embodiments described above. In addition, some of the individual modules functionally included within a module may be included in the display device, and the others may also be provided separately from the display device. For example, the display device may include the display module 11, and the processor 12, the memory 13, and the power module 14 may be provided in a form of other devices within the electronic device 10 instead of the display device.

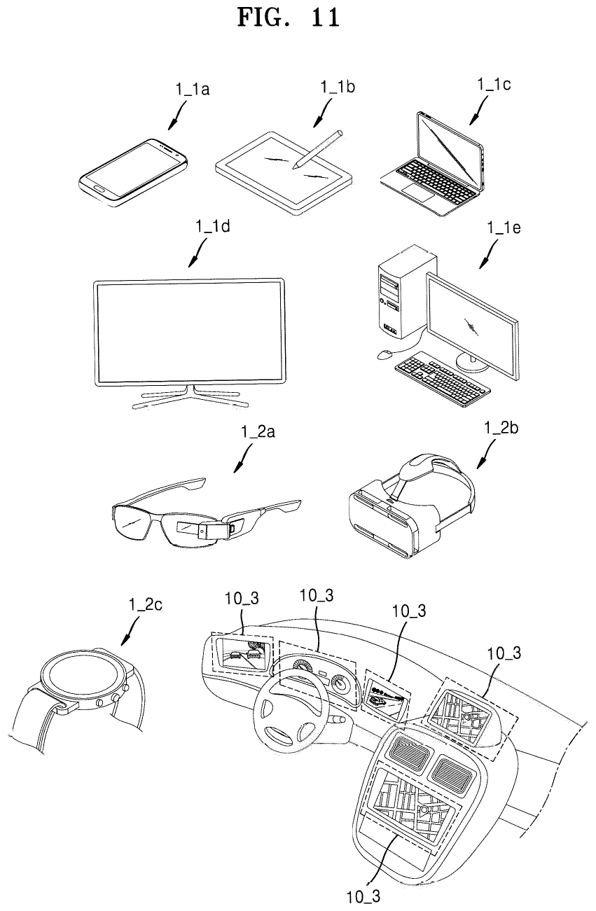

FIG. 11 shows schematic diagrams of electronic devices according to various embodiments.

Referring to FIG. 11, various electronic devices to which display devices according to embodiments are applied may not only include electronic devices for image display, such as a smartphone 1_1a, a tablet personal computer (PC) 1_1b, a laptop 1_1c, a television (TV) 1_1d, a desk monitor 1_1e, but may also include wearable electronic devices including display modules, such as smart glasses 1_2a, a head-mounted display 1_2b, a smart watch 1_2c, or the like, and electronic devices 10_3 for a vehicle including a display module, such as a dashboard of a vehicle, a center fascia, a center information display (CID) disposed on a dashboard, a room mirror display, or the like.

According to some example embodiments, the durability and/or the quality of a display device may be improved.

Effects of inventive concepts are not limited to the effects mentioned above, and other effects not mentioned will be clearly understood by one of ordinary skill in the art from the description of the claims.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

It should be understood that example embodiments described herein should be considered in a descriptive sense only and not for purposes of limitation. Descriptions of features or aspects within each embodiment should typically be considered as available for other similar features or aspects in other embodiments. While one or more example embodiments have been described with reference to the figures, it will be understood by those of ordinary skill in the art that various changes in form and details may be made therein without departing from the spirit and scope as defined by the following claims.

What is claimed is:

1. A display device comprising a display panel having a display area and a peripheral area, wherein the display panel comprises:
a substrate;
a thin-film transistor on the substrate, at least partly in the display area and comprising a semiconductor layer, a gate electrode, a source electrode, and a drain electrode;
a planarization insulating layer on the thin-film transistor, at least partly in the display area and in the peripheral area;
a pixel electrode on the planarization insulating layer, at least partly in the display area and electrically connected to the thin-film transistor;
an alignment mark on the planarization insulating layer, at least partly in the peripheral area and comprising a first conductive layer; and
a bank layer on the planarization insulating layer, covering a portion of the pixel electrode and defining a pixel opening, the pixel opening exposing the portion of the pixel electrode,
wherein the pixel electrode and the first conductive layer are in a same layer and comprise a same material, and
the first conductive layer is apart from the bank layer.

2. The display device of claim 1, wherein the first conductive layer comprises:
a first portion;
a second portion on the first portion and comprising a different material from the first portion; and
a third portion on the second portion and comprising a same material as the first portion.

3. The display device of claim 2, wherein
each of the first portion and the third portion comprises an indium tin oxide (ITO) material, and
the second portion comprises a silver (Ag) material.

4. The display device of claim 1, wherein
the display panel further comprises a second conductive layer between the substrate and the planarization insulating layer and at least partly in the peripheral area, and
the second conductive layer is in a same layer as each of the source electrode and the drain electrode and comprises a same material as each of the source electrode and the drain electrode.

5. The display device of claim 4, wherein the first conductive layer is surrounded by the second conductive layer in a plan view.

6. The display device of claim 5, wherein each of the second conductive layer, the source electrode, and the drain electrode independently comprises at least one material from among titanium (Ti) and aluminum (Al).

7. The display device of claim 1, further comprising:
an optical functional layer on the display panel,
wherein the optical functional layer is aligned with the display panel by the alignment mark.

8. The display device of claim 7, wherein the optical functional layer comprises a polarizing plate.

9. The display device of claim 7, further comprising:
a planarization layer between the optical functional layer and the display panel.

10. The display device of claim 7, further comprising:
a cover window on the optical functional layer.

11. An electronic device comprising a display panel, the display panel having a display area and a peripheral area, wherein the display panel comprises:
a substrate;
a thin-film transistor on the substrate, at least partly in the display area and comprising a semiconductor layer, a gate electrode, a source electrode, and a drain electrode;
a planarization insulating layer on the thin-film transistor, at least partly in the display area and the peripheral area;
a pixel electrode on the planarization insulating layer, at least partly in the display area and electrically connected to the thin-film transistor;
an alignment mark on the planarization insulating layer, at least partly in the peripheral area and comprising a first conductive layer;
a second conductive layer between the substrate and the planarization insulating layer, at least partly in the peripheral area; and
a bank layer on the planarization insulating layer to cover a portion of the pixel electrode and defining a pixel opening exposing the portion of the pixel electrode,
wherein the first conductive layer is spaced apart from the bank layer, and
the first conductive layer is surrounded by the second conductive layer in a plan view.

12. The electronic device of claim 11, wherein the pixel electrode and the first conductive layer are in a same layer and comprise a same material.

13. The electronic device of claim 11, wherein the second conductive layer is in a same layer as each of the source electrode and the drain electrode, and comprises a same material as each of the source electrode and the drain electrode.

14. The electronic device of claim 11, wherein the first conductive layer comprises:
a first portion;
a second portion on the first portion and comprising a different material from the first portion; and
a third portion on the second portion and comprising a same material as the first portion.

15. The electronic device of claim 14, wherein
each of the first portion and the third portion comprises an indium tin oxide (ITO) material, and
the second portion comprises a silver (Ag) material.

16. The electronic device of claim 11, wherein each of the second conductive layer, the source electrode, and the drain electrode independently comprise at least one material from among titanium (Ti) and aluminum (Al).

17. The electronic device of claim 11, further comprising:
an optical functional layer on the display panel,
wherein the optical functional layer is aligned with the display panel by the alignment mark.

18. The electronic device of claim 17, wherein the optical functional layer comprises a polarizing plate.

19. The electronic device of claim 17, further comprising:
a planarization layer arranged between the optical functional layer and the display panel.

20. The electronic device of claim 17, further comprising:
a cover window on the optical functional layer.
